(19) United States
(12) Patent Application Publication
(10) Pub. No.: US 2015/0380397 A1
(43) Pub. Date: Dec. 31, 2015

(54) ESD Protection for Advanced CMOS Processes

(71) Applicant: Apple Inc., Cupertino, CA (US)

(72) Inventors: Sanjay Dabral, Cupertino, CA (US); Xiaofeng Fan, Santa Clara, CA (US)

(21) Appl. No.: 14/501,773

(22) Filed: Sep. 30, 2014

Related U.S. Application Data
(60) Provisional application No. 62/018,251, filed on Jun. 27, 2014.

(51) Int. Cl. H01L 27/02

(52) U.S. Cl. CPC H01L 27/0266; H01L 27/0255; H01L 27/0288

(57) ABSTRACT

Various embodiments of ESD protection circuits and methods for operating the same are disclosed. In one embodiment, one or more driver circuits are protected by a first ESD protection circuit configured to activate and discharge current responsive to an ESD event. The driver circuit may include a pull-up transistor and a pull-down transistor each coupled to drive an output node. A second ESD protection circuit may be associated with and dedicated to the pull-up transistor in the driver circuit.

### PRIORITY INFORMATION

This application claims priority to U.S. provisional patent application Ser. No. 62/018,251, entitled “ESD Protection for Advanced CMOS Processes”, filed Jun. 27, 2014, and which is hereby incorporated by reference in its entirety as though fully and completely set forth herein.

### BACKGROUND

1. Technical Field

This disclosure is directed to electronic circuits, and more particularly, to providing protection of electronic circuits from damage resulting from electro-static discharge (ESD).

2. Description of the Related Art

Electro-static discharge (ESD) is a sudden electrical current flow between two charged surfaces. Often times, a significant difference in voltage potential may exist between the two charged surfaces. When the surfaces are electrically shorted together, come into contact, or dielectric breakdown occurs there between, the surfaces may discharge until the difference in voltage is effectively zero. Since the voltage difference prior to discharge may be large, the corresponding currents during discharge may also be large.

Semiconductor devices (e.g., integrated circuits, or ICs) may be particularly vulnerable to the adverse effects of ESD. The large currents that can be produced by ESD can damage or destroy circuitry. Accordingly, during manufacturing and installation of electronic systems utilizing ICs, special handling procedures may be followed to prevent ESD damage from occurring. Furthermore, many ICs may have ESD protection circuitry built therein. Such circuitry may include a sensor and a clamp circuit. The sensor may sense the occurrence of an ESD event. Responsive to sensing the ESD event, the sensor may cause activation of the clamp circuit to provide an electrical path through which the current may be safely discharged.

### SUMMARY

Various embodiments of ESD protection circuits and methods for operating the same are disclosed. In one embodiment, one or more driver circuits are protected by a first ESD protection circuit configured to activate and discharge current responsive to an ESD event. The driver circuit may include a pull-up transistor and a pull-down transistor each coupled to drive an output node. A second ESD protection circuit may be associated with and dedicated to the pull-up transistor in the driver circuit. The second ESD circuit may also activate responsive to an ESD event to enable the discharging of current while preventing damage to the pull-up transistor.

The second ESD circuit may be implemented in various ways. In one embodiment, a diode or number of diodes may be coupled in a series configuration in parallel with the pull-up transistor, between a power node and an output node of the driver circuit. The diodes may provide a discharge path in parallel with the pull-up transistor during an ESD event. In another embodiment, the second ESD circuit may be implemented as a trigger circuit coupled to activate the pull-up transistor responsive to an ESD event. At least some of the current resulting from the ESD event may then be discharged through the pull-up transistor. In yet another event, another transistor may be implemented in parallel with the pull-up transistor, and may be activated responsive to an ESD event, thereby providing a parallel path for discharging the resulting current.

In one embodiment, a driver circuit may be implemented with additional resistors coupled between the pull-up and pull-down transistors and a respective output node. The extra resistors may reduce the ESD stress on the drivers during an ESD event. Such driver circuits may be implemented in conjunction with one or more ESD protection circuits including those discussed above.

### BRIEF DESCRIPTION OF THE DRAWINGS

The following detailed description makes reference to the accompanying drawings, which are now briefly described.

FIG. 1 is a schematic diagram illustrating one embodiment of a driver circuit coupled to first and second ESD protection circuits.

FIG. 2 is a schematic diagram illustrating one embodiment of a driver circuit having a second ESD protection circuit dedicated to a pull-up transistor.

FIG. 3 is a schematic diagram illustrating another embodiment of a driver circuit having a second ESD protection circuit dedicated to a pull-up transistor.

FIG. 4 is a schematic diagram illustrating embodiment of a driver circuit having a second ESD protection circuit dedicated to a pull-up transistor.

FIG. 5 is a schematic diagram illustrating an embodiment of a driver circuit with alternate connections to an output node.

FIG. 6 is a flow diagram illustrating one embodiment of a method for operating multiple ESD protection circuits responsive to detection of an ESD event.

FIG. 7 is a block diagram of one embodiment of an exemplary system.

While the disclosed subject matter is susceptible to various modifications and alternative forms, specific embodiments thereof are shown by way of example in the drawings and will herein be described in detail. It should be understood, however, that the drawings and detailed description thereto are not intended to limit the subject matter to the particular form disclosed, but on the contrary, the intention is to cover all modifications, equivalents and alternatives falling within the spirit and scope of the disclosed subject matter as defined by the appended claims. The headings used herein are for organizational purposes only and are not meant to be used to limit the scope of the description. As used throughout this application, the word “may” is used in a permissive sense (i.e., meaning having the potential to), rather than the mandatory sense (i.e., meaning must). Similarly, the words “include”, “including”, and “includes” mean including, but not limited to.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits and/or memory storing program instructions executable to implement the operation. The memory can include volatile memory such as static or dynamic random access memory and/or nonvolatile memory such as optical or magnetic disk storage, flash memory, programmable read-only memories, etc. Similarly, various units/circuits/components may be described as performing a task or tasks, for convenience in the description. Such descriptions should be interpreted as including the phrase “configured to.” Reciting a unit/circuit/component that is configured to perform one or more tasks is expressly intended not to invoke 35 U.S.C. §112, paragraph (f) interpretation for that unit/circuit/component.

### DETAILED DESCRIPTION OF EMBODIMENTS

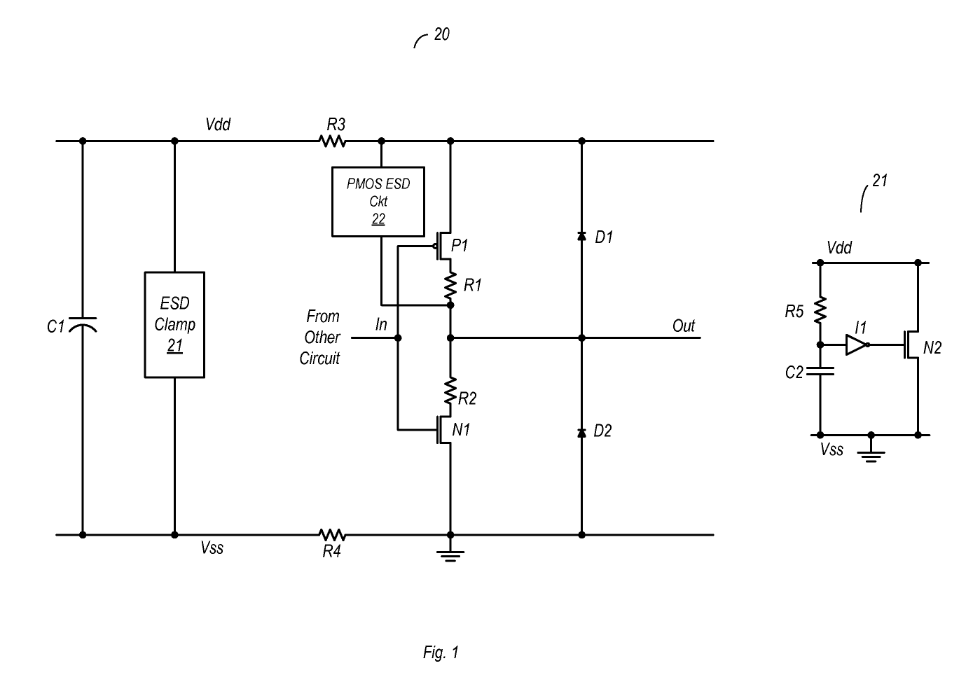

Turning now to FIG. 1, a schematic diagram of one embodiment of a circuit including a driver circuit protected by ESD protection circuits is disclosed. In the embodiment shown, a driver circuit includes a pull-up transistor P1 and a pull-down transistor N1. The pull-up transistor P1 may be implemented as a p-channel metal oxide semiconductor (PMOS) transistors, while the pull-down transistor N1 may be implemented as an N-channel metal oxide semiconductor (NMOS) transistor. An input node (‘In’) is coupled to the respective gate terminals of P1 and N1. Both P1 and N1 are coupled to drive an output node (‘Out’) through respectively coupled resistors R1 and R2, which are optional, or alternatively, may represent parasitic resistances rather than actual resistors. Diodes D1 is provided in order to maintain a low voltage between the output node and Vdd, while diode D2 is provided in order to maintain a low voltage between Vss and the output node.

In this embodiment, the driver circuit may function as a simple inverter. However, the various embodiments of ESD circuitry discussed below are not limited to use with the driver circuit shown in FIG. 1. In contrast, the ESD circuitry discussed herein may be used with a wide variety of circuits not otherwise discussed in this disclosure.

In the example shown, circuit 20 includes two ESD protection circuits, ESD clamp 21 and PMOS ESD circuit 22. These ESD protection circuits may provide respective discharge paths for current responsive to the occurrence of an ESD event. As defined herein, an ESD event is a rapid discharge of current between two differently charged objects due to contact, an electrical short, or dielectric breakdown. For example, a human may in the course of normal activities build up a static electric field on his or her person. When coming into contact with another differently charged object, the differing charges (and thus potentials) may cause a sudden flow of current there between. This current can be significant (e.g., in the ampere range) due to large charge, and thus potential differences. In the case of circuit 20 when not operating, large potentials may exist between the power node (‘Vdd’) and the reference node (‘Vss’) due to static electricity or some other cause. When an event occurs that results in a rapid discharge of current between these nodes, damage to devices in the circuit may occur if a safe discharge path is not provided. ESD clamp 21 and PMOS ESD circuit 22 are thus provided to activate respective paths for safely discharging current responsive to detection of an ESD event.

ESD clamp 21 is an ESD protection circuit configured to provide protection against ESD events for the entire driver circuit. An example of one embodiment of a circuit used to implement ESD clamp 21 is shown on the right-hand portion of the drawing. ESD clamp 21 in this embodiment includes a resistor R5 and a capacitor C2 coupled in series between Vdd and Vss. The junction between R5 and C2 is coupled to the input of inverter I1, while the output of this inverter is coupled to a gate terminal of transistor N2. The drain and source terminals of N2 are coupled to Vdd and Vss, respectively. When an ESD event occurs, the current through R5 and C2 may cause the input of I1 to fall low. As a result, the output of I1 may transition high, thereby activating N2. When N2 is active, a discharge path for current between Vdd and Vss is created. Accordingly, current resulting from the ESD event may be safely discharged through N2.

It is noted that ESD clamp 21 shown here is an exemplary embodiment, and other circuit embodiments may be used to implement this circuit. In contrast, any suitable ESD protection circuitry may be used to implement ESD clamp 21.

Circuit 21 also includes an additional ESD protection circuit, PMOS ESD circuit 22. As is discussed below, PMOS ESD circuit 22 may be implemented in a number of different ways. PMOS ESD circuit 22 may provide additional ESD protection exclusively to pull-up transistor P1. The extra protection may be provided for the PMOS transistors implementing P1 due to its increased vulnerability to damage from ESD events. Generally speaking, a PMOS transistor may have a much lower snap-back voltage than a corresponding NMOS transistor. Furthermore, a PMOS transistor may be susceptible to damage from much lower levels of current during an ESD event. Accordingly, extra protection dedicated to the PMOS transistor P1 is provided in the various embodiments of circuit 20 shown in FIGS. 1-5.

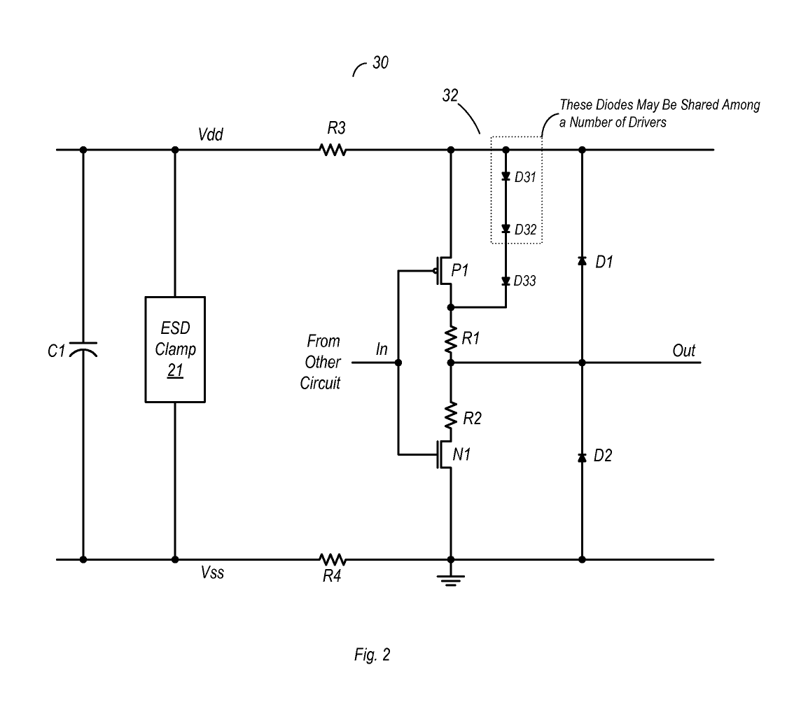

FIG. 2 is a schematic diagram illustrating one embodiment of a driver circuit 30 having a second ESD protection circuit dedicated to a pull-up transistor. Driver circuit 30 as shown in FIG. 2 is arranged similarly to driver circuit 20, including a number of corresponding circuit elements. In the embodiment shown, the pull-up transistor P1 is coupled to receive extra ESD protection from PMOS ESD circuit 32. As shown in FIG. 2, PMOS ESD circuit 32 is implemented using diodes (D31, D32, and D33 in this example).

The diodes are coupled in series between Vdd and the junction of P1 and R1. Thus, PMOS ESD circuit 32 is arranged in this embodiment to provide a current path parallel to P1 for discharging current resulting from an ESD event.

As noted in the embodiment shown, at least some of the diodes may be shared among a number of different driver circuits. In this example, diodes D31 and D32 are shared with among a number of different driver circuits, while D33 is dedicated to P1 of driver circuit 30. The number of shared diodes may vary from one embodiment to the next, as may the number of dedicated diodes. Furthermore, in some instances of circuit 30, each of the diodes can be dedicated to protecting P1 without being shared with other circuits.

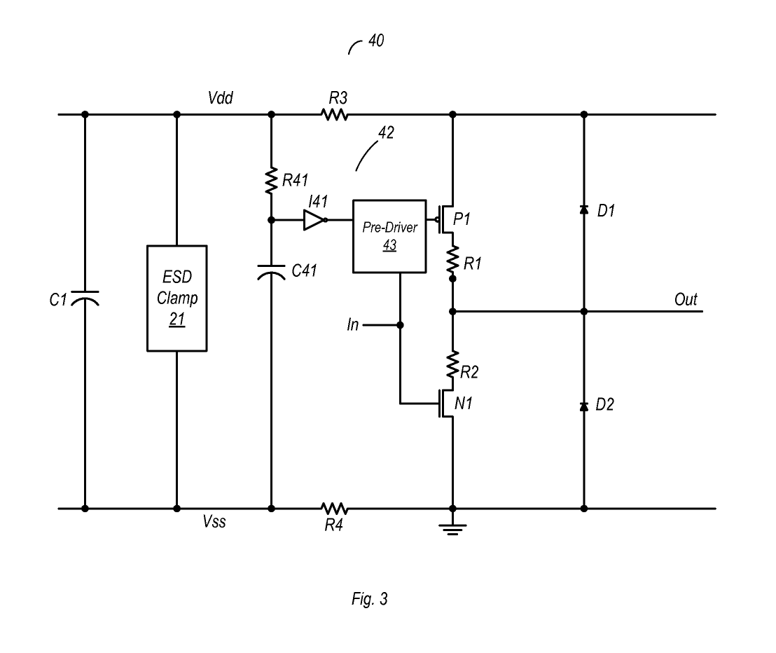

FIG. 3 is an embodiment of a circuit 40 that includes another embodiment of a second ESD protection circuit. In this particular embodiment, PMOS ESD circuit 42 is configured to activate transistor P1 responsive to an ESD event. PMOS ESD circuit 42 in the embodiment shown includes resistor R41 and capacitor C41 coupled together in series between Vdd and Vss. The junction of R41 and C41 is coupled to inverter 141, which in turn has an output coupled to pre-driver circuit 43. The pre-driver circuit 42 is also coupled to the input node, and is configured to pass a signal received on the input node to the gate terminal of P1.

When an ESD event occurs, a signal may be generated on the junction of R51 and C51, which may then be input into inverter I51. Responsive thereto, inverter I51 may output a corresponding signal to pre-driver circuit 43. As a result, pre-driver circuit 43 may output a logic low on the gate terminal of P1, thereby activating the transistor. When activated, P1 may provide a path to discharge some of the current resulting from the ESD event. It is noted that in this particular embodiment, P1 may be sized to handle current at higher gate-source voltages than may be necessary for normal logic operations.

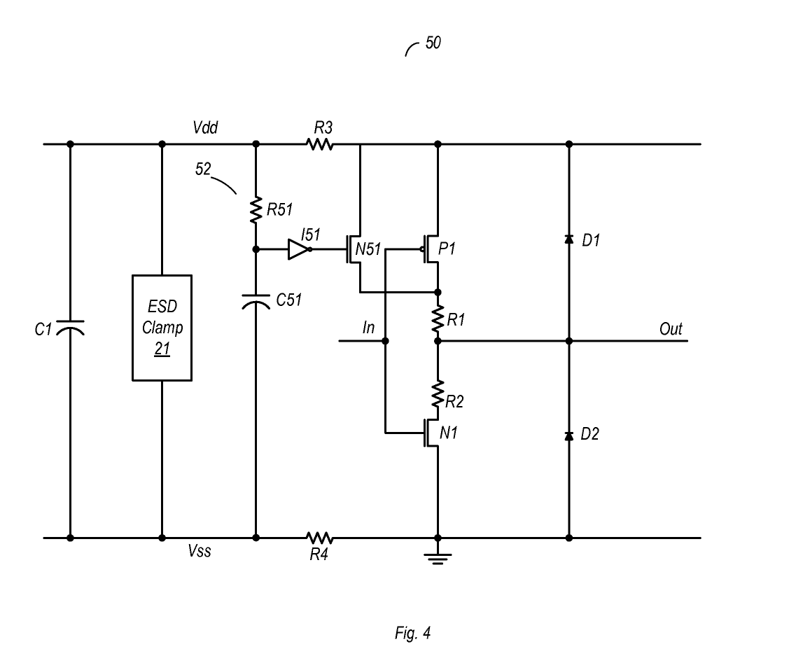

FIG. 4 is a schematic diagram illustrating embodiment of a driver circuit having a second ESD protection circuit dedicated to a pull-up transistor. In this particular embodiment, an NMOS transistor N51 is coupled in parallel with transistor P1. Responsive to an ESD event, the junction of resistor R51 and capacitor C51 may fall to a logic low voltage, resulting in inverter I51 outputting a logic high voltage. The logic high voltage is received on the gate terminal of N51, thereby activating the device. When N51 is active, a current path that is parallel to transistor P1 is provided, thereby allowing at least some of the current from the ESD event to be discharged. In various embodiments, N51 may be sized to handle a larger current than P1, and more particularly, a current expected from an ESD event.

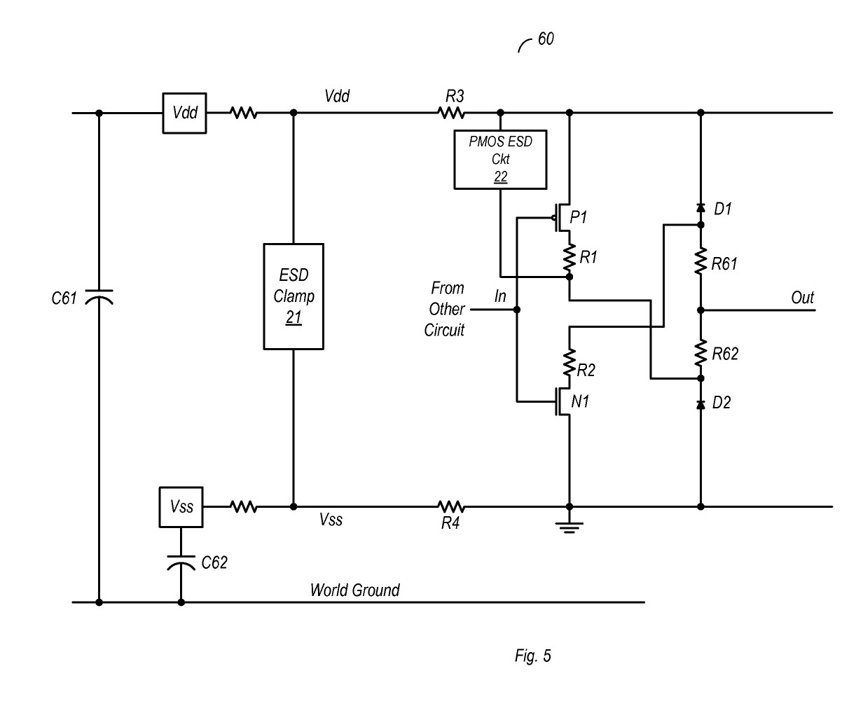

FIG. 5 is a schematic diagram illustrating an embodiment of a driver circuit with alternate connections to an output node. In the embodiment shown, pull-up transistor P1 is connected to the output node through resistor R1 and resistor R62. Similarly, pull-down transistor N1 is coupled to the output node through resistor R2 and resistor R61. The extra resistors implemented in the circuit may reduce ESD stress on the driver circuit relative to embodiments that do not use them.

In the embodiment shown, circuit 60 includes PMOS ESD circuit 22, which may be implemented as any one of the embodiments shown in FIGS. 2-4 or other embodiments not explicitly discussed herein. It is noted however that some embodiments of circuit 60 may be implemented without a PMOS ESD circuit 22.

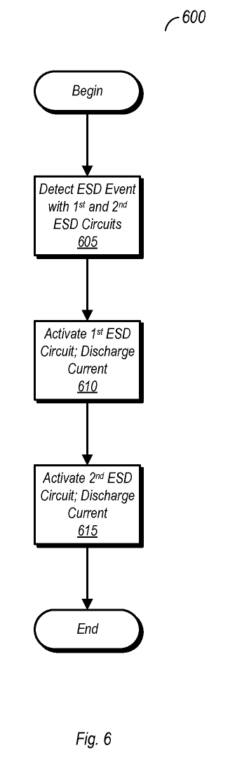

FIG. 6 is a flow diagram illustrating one embodiment of a method for operating multiple ESD protection circuits responsive to detection of an ESD event. Method 600 may be performed using any of the circuit embodiments discussed above. It is further contemplated that method 600 may be performed with circuit embodiments not explicitly discussed herein.

Method 600 begins with the detection of an ESD event by first and second ESD protection circuits (block 605). The first ESD protection circuit may be a general ESD protection circuit that provides protection for a number of drivers and/or other circuitry. The second ESD protection circuit may be dedicated to a PMOS transistor of a specific circuit, such as a driver circuit (although other types of circuits utilizing PMOS transistors, such as various logic gates, may also utilize a dedicated ESD protection circuit).

Responsive to the ESD event, the first ESD protection circuit may be activated to discharge current (block 610). The current may be discharged between a power node and a reference (e.g., ground) node. The second ESD protection circuit may also be activated to discharge current (block 615). The second ESD protection circuit may discharge current in parallel with the PMOS transistor, or in some embodiments, through the PMOS transistor by activating it responsive to the ESD event.

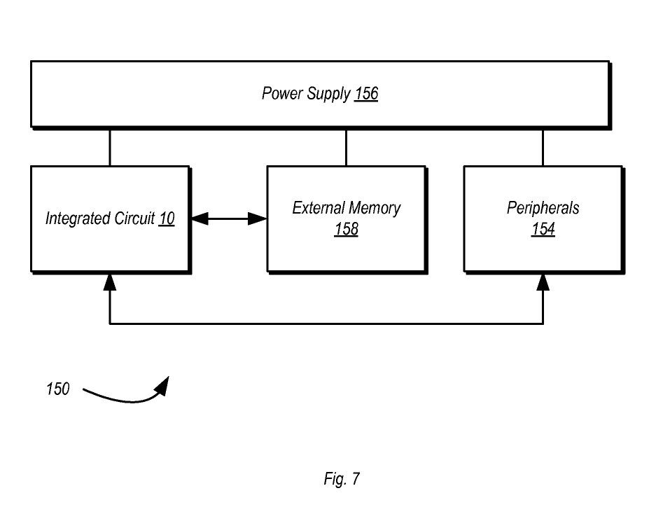

Turning next to FIG. 7, a block diagram of one embodiment of a system 150 is shown. In the illustrated embodiment, the system 150 includes at least one instance of the integrated circuit 10 coupled to external memory 158. The integrated circuit 10 is coupled to one or more peripherals 154 and the external memory 158. A power supply 156 is also provided which supplies the supply voltages to the integrated circuit 10 as well as one or more supply voltages to the memory 158 and/or the peripherals 154. In some embodiments, more than one instance of the integrated circuit 10 may be included (and more than one external memory 158 may be included as well).

The peripherals 154 may include any desired circuitry, depending on the type of system 150. For example, in one embodiment, the system 150 may be a mobile device (e.g. personal digital assistant (PDA), smart phone, etc.) and the peripherals 154 may include devices for various types of wireless communication, such as WiFi, Bluetooth, cellular, global positioning system, etc. The peripherals 154 may also include additional storage, including RAM storage, solid-state storage, or disk storage. The peripherals 154 may include user interface devices such as a display screen, including touch display screens or multitouch display screens, keyboard or other input devices, microphones, speakers, etc. In other embodiments, the system 150 may be any type of computing system (e.g. desktop personal computer, laptop, workstation, tablet, etc.).

The external memory 158 may include any type of memory. For example, the external memory 158 may be SRAM, dynamic RAM (DRAM) such as synchronous DRAM (SDRAM), double data rate (DDR, DDR2, DDR3, LPDDR1, LPDDR2, etc.) SDRAM, RAMBUS DRAM, etc. The external memory 158 may include one or more memory modules to which the memory devices are mounted, such as single inline memory modules (SIMMs), dual inline memory modules (DIMMs), etc.

Numerous variations and modifications will become apparent to those skilled in the art once the above disclosure is fully appreciated. It is intended that the following claims be interpreted to embrace all such variations and modifications.

What is claimed is:

1. A circuit comprising:
a driver comprising a first transistor coupled between a power node and an output node and a second transistor coupled between the output node and a reference node;
a first electrostatic discharge (ESD) protection circuit configured to provide protection for the driver responsive to detection of an ESD event; and
a second ESD protection circuit configured to provide protection exclusively to the first transistor responsive to detection of the ESD event.

2. The circuit as recited in claim 1, wherein the first transistor is a p-channel metal oxide semiconductor (PMOS) transistor and wherein the second transistor is a first n-channel metal oxide semiconductor (NMOS) transistor.

3. The circuit as recited in claim 2, wherein the second ESD protection circuit comprises one or more series-coupled diodes connected in parallel with the first transistor between the power node and the output node.

4. The circuit as recited in claim 3, wherein the second ESD protection circuit comprises a plurality of series-coupled diodes shared among a plurality of additional drivers and at least one additional diode coupled in series between the output node of the driver and the plurality of series-coupled diodes, wherein the at least one additional diode is dedicated to the driver.

5. The circuit as recited in claim 2, wherein the second ESD protection circuit comprises a trigger circuit configured to activate the first transistor responsive to detecting the ESD event.

6. The circuit as recited in claim 2, further comprising a trigger circuit and a second NMOS transistor coupled in parallel with the first transistor between the power node and the output node, wherein the trigger circuit is configured to activate the second NMOS transistor responsive to detecting the ESD event.

7. The circuit as recited in claim 1, wherein the first ESD protection circuit comprises an ESD clamp circuit coupled between the power node and the reference node.

8. The circuit as recited in claim 1, further comprising a first diode having its anode coupled to the output node and its cathode couple to the power node, and a second diode having its cathode coupled to the output node and its anode coupled to the reference node.

9. The circuit as recited in claim 1, further comprising:
a first resistor, wherein a first terminal of the first resistor is coupled to the output node;
a first diode having its anode coupled to a second terminal of the first resistor and its cathode coupled to the power node;
a second resistor, wherein a first terminal of the second resistor is coupled to the output node; and
a second diode having its cathode coupled to a second terminal of the second resistor and its anode coupled to the reference node.

10. The circuit as recited in claim 9, further comprising a third resistor coupled between a drain terminal of the first transistor and the cathode of the second diode, and a fourth resistor coupled between a drain terminal of the second transistor and an anode of the first diode.

11. A method comprising:
first and second electro-static discharge (ESD) protection circuits detecting an ESD event;
activating a first discharge path using the first ESD protection circuit to protect first and second transistors of a driver circuit; and
activating a second discharge path using the second ESD protection circuit to provide exclusive protection to the first transistor of the driver circuit.

12. The method as recited in claim 11, wherein the first transistor is a p-channel metal oxide semiconductor (PMOS) transistor having a source terminal coupled to a power node, and wherein the second transistor is a first n-channel metal oxide semiconductor (NMOS) transistor having a source terminal coupled to a reference node, and wherein the method further comprises:
the first transistor, when active, driving a signal on an output node of the driver circuit; and
the second transistor, when active, driving a signal on the output node.

13. The method as recited in claim 12, wherein the second ESD protection circuit comprises one or more diodes coupled in series between the power node and the output node, wherein the method further comprises the one or more diodes discharging current responsive to an ESD event.

14. The method as recited in claim 12, wherein the second ESD protection circuit comprises a trigger circuit coupled to the first transistor, and wherein the method further comprises the trigger circuit activating the first transistor responsive to the ESD event.

15. The method as recited in claim 12, wherein the second ESD protection circuit comprises a second NMOS transistor coupled between the power node and the output node, and wherein the method further comprises activating the second NMOS transistor responsive to the ESD event.

16. The method as recited in claim 12, wherein activating the first discharge path comprises activating a first clamp circuit coupled between the power node and the reference node.

17. A circuit comprising:
a driver circuit including a pull-up transistor coupled to a power node and a pull-down transistor coupled to a reference node, wherein each of the pull-up and pull-down transistors are configured to, when active, drive a signal onto an output node, wherein the driver circuit further includes:
a first resistor, wherein a first terminal of the first resistor is coupled to the output node;
a first diode having its anode coupled to a second terminal of the first resistor and its cathode coupled to the power node;
a second resistor, wherein a first terminal of the second resistor is coupled to the output node; and
a second diode having its cathode coupled to a second terminal of the second resistor and its anode coupled to the reference node;
a third resistor coupled between a drain terminal of the pull-up transistor and the cathode of the second diode; and
a fourth resistor coupled between a drain terminal of the pull-down transistor and an anode of the first diode; and
a first electrostatic discharge (ESD) protection circuit configured to provide protection for the driver responsive to detection of an ESD event.

18. The circuit as recited in claim 17, further comprising a second ESD protection circuit configured to provide protection exclusively to the pull-up transistor responsive to detection of the ESD event.

19. The circuit as recited in claim 17, wherein the second ESD protection circuit comprises one or more series-coupled diodes connected in parallel with the pull-up transistor between the power node and the output node.

20. The circuit as recited in claim 17, wherein the second ESD protection circuit comprises an n-channel metal-oxide semiconductor (NMOS) transistor coupled in parallel with the pull-up transistor.
